(19) United States
(12) Patent Application Publication
(10) Pub. No.: US 2024/0054178 A1
(43) Pub. Date: Feb. 15, 2024

(54) FACTORIZING VECTORS BY UTILIZING RESONATOR NETWORKS

(71) Applicant: International Business Machines Corporation, Armonk, NY (US)

(72) Inventors: Jovin Langenegger, Gerlikon (CH); Kumudu Geethan Karunaratne, Gattikon (CH); Michael Andreas Hersche, Zurich (CH); Abu Sebastian, Adliswil (CH); Abbas Rahimi, Rüschlikon (CH)

(21) Appl. No.: 17/819,237

(22) Filed: Aug. 11, 2022

(51) Int. Cl. G06F 17/16; G06K 9/62; G06F 9/30

(52) U.S. Cl. CPC G06F 17/16; G06K 9/6215; G06F 9/30036

(57) ABSTRACT

The disclosure includes a computer-implemented method of factorizing a vector by utilizing resonator network modules. Such modules include an unbinding module, as well as search-in-superposition modules. The method includes the following steps. A product vector is fed to the unbinding module to obtain unbound vectors. The latter represent estimates of codevectors of the product vector. A first operation is performed on the unbound vectors to obtain quasi-orthogonal vectors. The first operation is reversible. The quasi-orthogonal vectors are fed to the search-in-superposition modules, which rely on a single codebook. In this way, transformed vectors are obtained, utilizing a single codebook. A second operation is performed on the transformed vectors. The second operation is an inverse operation of the first operation, which makes it possible to obtain refined estimates of the codevectors.

### BACKGROUND

The disclosure relates in general to the field of computer-implemented methods, computerized systems, and computer program products, for factorizing vectors by utilizing resonator network modules. In particular, it is directed to a method of factorizing a product vector by utilizing resonator network modules, based on a single codebook and quasi-orthogonal vector representations of unbound vectors representing estimates of codevectors of the product vector, where the estimates of the codevectors are iteratively refined.

### SUMMARY

According to a first aspect, the present disclosure is embodied as a computer-implemented method of factorizing a vector by utilizing resonator network modules. Such modules include an unbinding module, as well as search-in-superposition modules. The method includes the following steps. A product vector is fed to the unbinding module to obtain unbound vectors. The latter represent estimates of codevectors of the product vector. A first operation is performed on the unbound vectors to obtain quasi-orthogonal vectors. The first operation is reversible. The quasi-orthogonal vectors are fed to the search-in-superposition modules, which rely on a single codebook. In this way, transformed vectors are obtained, by utilizing a single codebook. A second operation is performed on the transformed vectors. The second operation is an inverse operation of the first operation, which makes it possible to obtain refined estimates of the codevectors.

### BRIEF DESCRIPTION OF THE DRAWINGS

These and other objects, features and advantages of the present disclosure will become apparent from the following detailed description of illustrative embodiments thereof, which is to be read in connection with the accompanying drawings. The illustrations are for clarity in facilitating one skilled in the art in understanding the disclosure in conjunction with the detailed description. In the drawings:

FIG. 1 is a diagram illustrating computational phases of a resonator network, where such computational phases are successively and iteratively performed by resonator network modules of the resonator network, with a view to factorizing a product vector, according to embodiments;

FIG. 2 is a diagram illustrating a non-conventional hardware device that is specifically designed to factorize a product vector, where the device notably includes a crossbar array structure, according to embodiments;

FIG. 3 is a flowchart illustrating high-level steps of a method of factorizing a product vector, according to embodiments; and

FIG. 4 schematically represents a general-purpose computerized system, suited for implementing one or more method steps as involved in embodiments of the disclosure.

The accompanying drawings show simplified representations of devices or parts thereof, as involved in embodiments. Technical features depicted in the drawings are not necessarily to scale. Similar or functionally similar elements in the figures have been allocated the same numeral references, unless otherwise indicated.

Computerized systems, methods, and computer program products embodying the present disclosure will now be described, by way of non-limiting examples. Note, the present method and its variants are collectively referred to as the “present methods”.

### DETAILED DESCRIPTION OF EMBODIMENTS OF THE DISCLOSURE

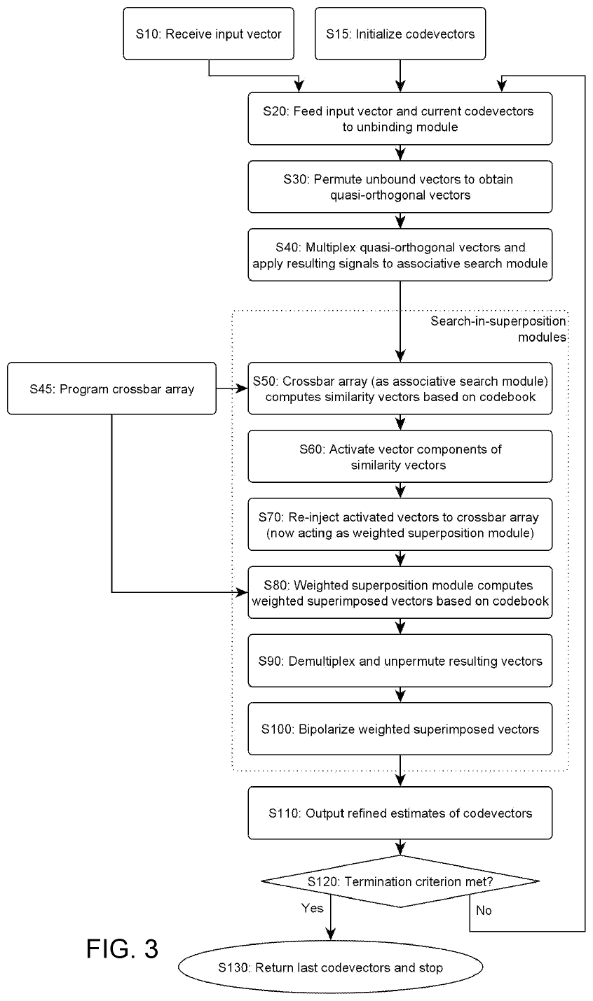

The following description is structured as follows. Embodiments of the disclosure are initially described in detail, following which technical implementation details of specific embodiments are provided in which the present methods are performed using conventional hardware. All references Sn refer to method steps of the flowcharts of FIG. 3, while solely numeral references pertain to devices, components, and concepts involved in embodiments of the present disclosure.

Resonator networks are used for factorizing high-dimensional vectors, also called hypervectors. A resonator network typically requires an unbinding module, which is coupled to search-in-superposition modules, which typically consist of an associative search module, and a weighted superposition module. Typically, such modules are operatively connected to iteratively refine the estimated vectors of the factors until a convergence towards the correct codevectors is achieved. For each factor, a dedicated codebook is used, which stores all possible codevectors.

In more detail, when a high-dimensional signal vector x, which is assumed to be constructed using the product of F factors, is presented to a resonator network, the latter is able to find the factors more quickly than other methods (e.g., a brute-force, least squares, iterative soft thresholding, or project gradient descent method).

As an example, consider a signal vector x constructed from F=3 factors sampled from three codebooks A, B, and C, i.e.,

A={α⁽¹⁾,α⁽²⁾,α^{(M}^{_{A)}}},

B={b⁽¹⁾, b⁽²⁾, b^{(M}^{_{B)}}}, and

C={c⁽¹⁾, c⁽²⁾, c^{(M}^{_{C)}}},

respectively including M_{A}, M_{B}, and M_{C} codevectors, which are D-dimensional bipolar vectors. I.e., the values of the vector components can either be −1 or +1, and it is not necessary that all the factors have an equally sized codebook.

Now, if a signal vector x=α⁽ⁱ⁾⊙b^{(j)}⊙c^{(k)} is presented to a resonator network with the aim to find α⁽ⁱ⁾, b^{(j)}, and c^{(k)}, where i, j, k∈{1, 2, . . . , M} and the ⊙ symbol denotes the Hadamard product operator, the resonator network first determines (first time step) estimate \hat{α}(1), \hat{b}(1), ĉ(1) of the codevectors, typically using an equal weighted average of all codebook elements or some randomly selected codevector. Such estimates are then successively processed through four phases, with a view to obtain refined estimates of the codevectors. Such phases are further iterated though several time steps t to gradually refine the codevector estimates. I.e., the four phases are successively executed at each time step t.

The following describes operations performed during each of the four phases, at any given time step t. In the first of the four phases, the unbound codevectors are estimated by unbinding with the signal vector x and the estimated codevectors from the rest of the codebooks, as for instance captured in Equations (1) below:

\tilde{α}(t)=xØ\hat{b}(t)Øĉ(t),

\tilde{b}(t)=xØ\tilde{α}(t)Øĉ(t), and

\tilde{c}(t)=xØ\hat{α}(t)Ø\hat{b}(t), (1)

where the symbol Ø denotes the Hadamard division operator.

In the second of the four alternating phases, the attention vector α (also called similarity vector herein) is produced by associative search across the corresponding codebook with respect to each of the unbound codevectors, as in Equations (2) below, using a matrix-vector-multiplication (MVM) operation.

α_{α}(t)=\tilde{α}(t)A^{T},

α_{b}(t)=\tilde{b}(t)B^{T}, and

α_{c}(t)=\tilde{c}(t)C^{T}. (2)

In the third of the four phases, the attention vectors α_{α}(t), α_{b}(t), α_{c}(t) are passed through a non-linear activation function ƒ to find the activated attentions, as shown in Equations (3):

α′_{α}(t)=ƒ(α_{α}(t)),

α′_{b}(t)=ƒ(α_{b}(t)), and

α′_{c}(t)=ƒ(α_{c}(t)). (3)

In the last of the four phases, codevectors estimates are weighted-superimposed and bipolarized, as seen in Equations (4):

\hat{α}(t+1)=sign(α′_{α}(t)A),

\hat{b}(t+1)=sign(α′_{b}(t)B), and

ĉ(t+1)=sign(α′_{c}(t)C). (4)

That an MVM operation is first performed based on the codebooks and the activated attention vector. Next, the resulting vectors are bipolarized using the sign function. The resulting estimates of the codevectors can then be further refined during a next time step unless a convergence is achieved. A resonator is said to have converged for a given signal vector x when all three estimate codevectors remain the same across consecutive time steps. I.e., \hat{α}(t+1)=\hat{α}(t), \hat{b}(t+1)=\hat{b}(t) and ĉ(t+1)=ĉ(t).

Despite the computational improvements provided by resonator networks, iterative steps as described above come at a high computational cost.

Aspect of the present disclosure are embodied as a computer program product, system, and computer-implemented method of factorizing a vector by utilizing resonator network modules. Such modules include an unbinding module, as well as search-in-superposition modules. The method includes the following steps. A product vector is fed to the unbinding module to obtain unbound vectors. The latter represent estimates of codevectors of the product vector. A first operation is performed on the unbound vectors to obtain quasi-orthogonal vectors. The first operation is reversible. The quasi-orthogonal vectors are fed to the search-in-superposition modules, which rely on a single codebook. In this way, transformed vectors are obtained, utilizing a single codebook. A second operation is performed on the transformed vectors. The second operation is an inverse operation of the first operation, which makes it possible to obtain refined estimates of the codevectors

Aspects of the present disclosure rely on quasi-orthogonal versions of current estimates of the codevectors (i.e., the unbound codevectors, as obtained after the unbinding step), which are fed to the next modules of the resonator network, with a view to determining refined estimates of the codevectors. This is achieved using a single codebook, which simplifies data memory accesses as well as the storage of the corresponding codebook data. In addition, the proposed approach makes it possible to multiplex the quasi-orthogonal vectors, with a view to processing them across a single channel, which substantially accelerates processing times too. Moreover, the proposed approach makes it possible to achieve scalable, hardware-friendly realization of the resonator network modules.

The above steps may be performed iteratively, until a convergence is achieved. That is, in embodiments, the method is iteratively performed, whereby steps of feeding the product vector, performing the first operation, feeding the quasi-orthogonal vectors, and performing the second operation, are repeatedly performed based on successively refined estimates of the codevectors.

The search-in-superposition modules may include an associative search module and a weighted superposition module. With this modular arrangement, feeding the quasi-orthogonal vectors to the search-in-superposition modules causes to sequentially: (i) feed the quasi-orthogonal vectors to the associative search module, for it to compute similarity vectors based on a transpose of the single codebook, and (ii) pass vectors obtained from the similarity vectors to the weighted superposition module, for it to compute weighted superimposed vectors based on the single codebook.

In embodiments, the step of feeding the quasi-orthogonal vectors to the search-in-superposition modules comprises: (i) multiplexing the quasi-orthogonal vectors obtained; and (ii) feeding the multiplexed vectors to the search-in-superposition modules to obtain transformed multiplexed vectors by utilizing the single codebook. In addition, the method further comprises, prior to performing the second operation, demultiplexing the transformed multiplexed vectors to obtain the transformed vectors. That is, instead of having n channels involving n codebooks, here a single channel and a single codebook are needed, which makes it possible to save storage space, as well as time and energy, given that a single codebook need be stored and loaded (in software implementations).

In embodiments, the single codebook is devised so as to be symmetric, such that it is equal to its transpose. Accordingly, a same representation of the single codebook can be used by each of the associative search module and the weighted superposition module. Such an approach is particularly advantageous when using non-conventional hardware involving a crossbar array structure, because a single processing device is needed, which stores all the required codevector values and can efficiently perform the operations of the associative search module and the weighted superposition module, each in one computational step. I.e., a same crossbar array structure can act as the associative search module and the weighted superposition module.

The crossbar array structure includes input lines and output lines arranged in rows and columns. The input lines and the output lines are interconnected via memory elements. In variants where the codebook is not symmetric, two crossbar array structures can be cascaded and used as the associative search module and the weighted superposition module, respectively. The codebook may be symmetric, such that the same crossbar array structure can successively play the role of the associative search module and the weighted superposition module. In each case, the memory elements of the crossbar array structure are programmed to configure the latter as the relevant module.

In embodiments, the search-in-superposition modules further includes an activation module. This module interconnects the associative search module with the weighted superposition module. Feeding the quasi-orthogonal vectors to the search-in-superposition modules further causes to: (i) pass the similarity vectors to the activation module, for the latter to selectively activate vector components of the similarity vectors and accordingly obtain activated vectors, and (ii) pass the activated vectors to the weighted superposition module. The activation module is embodied as a near-memory processing device, connected in output of the input lines of the crossbar array structure. The activation module can then re-inject the activated vectors to the input lines, from their outputs.

In some embodiments, the first operation is a vector-dependent permutation operation, which permutes vector components of the unbound vectors according to respective permutation schemes. I.e., vector components of each of the unbound vectors are permuted according to a respective one of the permutation schemes. The second operation permutes vector components of the transformed vectors according to inverses (i.e., inverse operations) of the respective permutation schemes.

In some embodiments, each of the respective permutation schemes involves cyclic shifting operations. For example, the cyclic shifting operations may cause the vector components of any k^{th} vector of the unbound vectors to cyclically shift by k−1. Such operations are quickly and efficiently performed.

According to another aspect, the disclosure is embodied as a computerized system for factorizing a vector. The system includes a resonator network unit, which is designed to enable an unbinding module and search-in-superposition modules. It further includes an input unit configured to feed a product vector to the unbinding module to obtain unbound vectors representing estimates of codevectors of the product vector. It also includes processor. Consistently with the above methods, the processor is configured to: perform a first operation on the unbound vectors to obtain quasi-orthogonal vectors, wherein the first operation is reversible; feed the quasi-orthogonal vectors to the search-in-superposition modules to obtain transformed vectors by utilizing a single codebook; and perform a second operation on the transformed vectors, wherein the second operation is an inverse operation of the first operation, with a view to obtaining refined estimates of the codevectors, in operation. The system may be configured to iteratively refine the estimates of the codevectors.

In some embodiments, the processor further comprises a multiplexing unit configured to multiplex the quasi-orthogonal vectors obtained by the processing unit into multiplexed signals and apply the multiplexed signals to the search-in-superposition modules. This, in operation, makes it possible to obtain output signals encoding transformed multiplexed vectors, utilizing the single codebook. The processor further includes a demultiplexing unit configured to read the output signals and demultiplex the transformed multiplexed vectors encoded therein to obtain the transformed vectors.

In some embodiments, the search-in-superposition modules includes: an associative search module, which is configured to compute similarity vectors based on the quasi-orthogonal vectors and a transpose of the single codebook; and a weighted superposition module, which is configured to compute weighted superimposed vectors based on vectors obtained from the similarity vectors and the single codebook.

In some embodiments, the search-in-superposition modules further includes an activation module interconnecting the associative search module with the weighted superposition module. The activation module may be configured to selectively activate vector components of the similarity vectors to accordingly obtain activated vectors and pass the activated vectors to the weighted superposition module. However, other types of activation functions can be contemplated, such as the softmax or tanh functions, which do not activate single entries but scale them according to a predefined operation.

In some embodiments, the resonator network unit includes a crossbar array structure including input lines and output lines arranged in rows and columns, which are interconnected via memory elements, which may be resistive memory elements. The system further includes programming means connected in input of the input lines and adapted to program the memory elements of the crossbar array structure to accordingly configure the crossbar array structure as said associative search module or said weighted superposition module. The system may possibly include several crossbar array structures, which are typically cascaded, as noted earlier.

In some embodiments, the processor includes a permutation unit configured to perform the first operation as a vector-dependent permutation operation, which is adapted to permute vector components of the unbound vectors according to respective permutation schemes. I.e., vector components of each of the unbound vectors are permuted according to a respective one of the respective permutation schemes, in operation. The permutation unit is further configured to perform the second operation as a vector-dependent, inverse permutation operation, which permutes vector components of the transformed vectors according to permutation schemes that are inverses of the respective permutation schemes, in operation.

In some embodiments, the permutation unit is adapted to implement each of the respective permutation schemes as cyclic shifting operations. The cyclic shifting operations may for instance cause the vector components of any k^{th} vector of the unbound vectors to cyclically shift by k−1, in operation.

The above system can involve non-conventional hardware, and/or it may also be realized using suitably configured, conventional hardware, so as to implement the present methods in software. In that respect, a final aspect of the disclosure concerns a computer program product for factorizing a vector by utilizing modules of a resonator network. Again, the modules include an unbinding module, as well as search-in-superposition modules. To that aim, the computer program product comprises a computer-readable storage medium having computer-readable program code embodied therewith. The computer-readable program code can be evoked by processor to cause the processor to: feed a product vector to the unbinding module to obtain unbound vectors representing estimates of codevectors of the product vector; perform a first operation on the unbound vectors to obtain quasi-orthogonal vectors, wherein the first operation is reversible; feed the quasi-orthogonal vectors to the search-in-superposition modules to obtain transformed vectors by utilizing a single codebook; and perform a second operation on the transformed vectors, wherein the second operation is an inverse operation of the first operation, to obtained refined estimates of the codevectors.

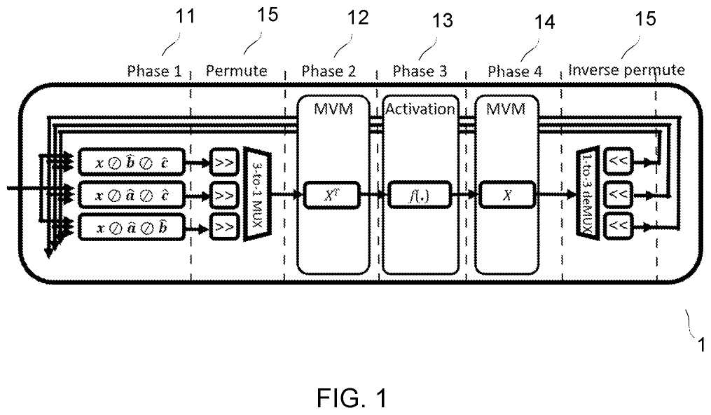

A first aspect of the disclosure is now described in reference to FIGS. 1-3. This aspect concerns a computer-implemented method of factorizing a vector by utilizing resonator network modules.

As depicted in FIG. 1, the resonator network modules 11-14 include an unbinding module 11, as well as search-in-superposition modules 12, 14. The search-in-superposition modules 12, 14 can involve an associative search module 12 and a weighted superposition module 14, as depicted in FIG. 1. In addition, the resonator network modules 11-14 may possibly include an activation module 13, which interconnects the associative search module 12 with the weighted superposition module 14.

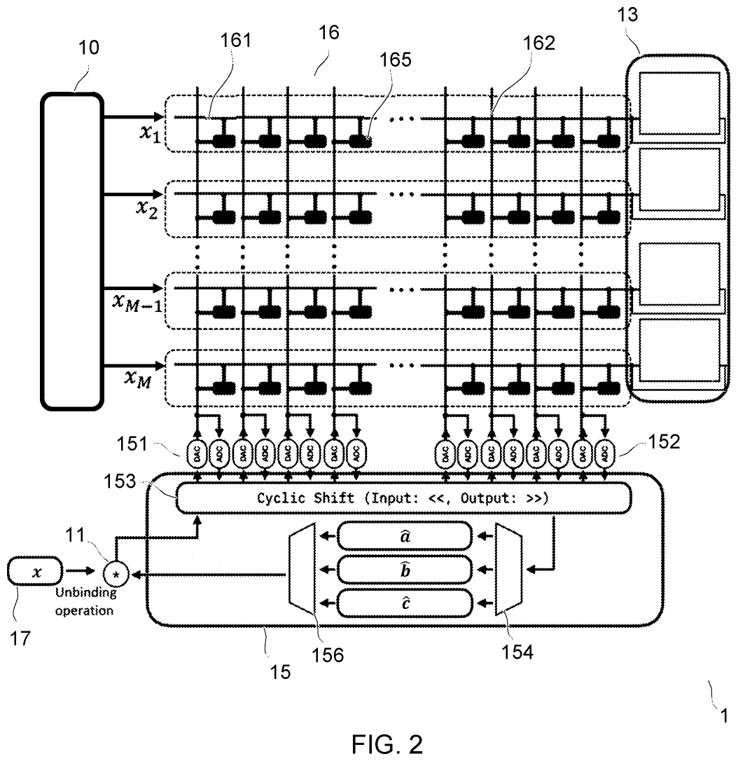

The method is implemented at a hardware device, apparatus, or system 1 (see FIG. 2 for an illustration), e.g., by some processor 15, 105 that orchestrates operations performed by the modules 11-14. The main steps of the method are the following.

First, a product vector is fed to the unbinding module 11 (see step S20 in FIG. 3), with a view to obtaining unbound vectors representing estimates of codevectors of the product vector. In the present context, the codevectors are high-dimensional vectors. The product vector is the vector to be factorized. This operation is typically performed as in Equations (1), see above.

Second, an operation is performed on the unbound vectors (step S30). This operation is reversible. It is further designed so that performing this operation obtains quasi-orthogonal vectors. The vectors obtained need to be at least quasi-orthogonal. They may possibly be strictly orthogonal, though this is not necessary, given the typical dimensions of the problem at issue, as discussed later in detail.

Third, the quasi-orthogonal vectors are fed S40 to the search-in-superposition modules 12, 14. The aim is to obtain S50-S80 transformed vectors utilizing a single codebook. such that the proposed method requires only a single codebook, as compared to prior approaches that often required numerous. Such operations can be compared to operations captured in Equations (2) and (4), with the possibility to insert operations as in Equation (3), except that only a single codebook is necessary.

Finally, a further operation is performed S90 on the transformed vectors. This operation is the inverse operation of the operation performed at step S30. For convenience, the operations performed at steps S30 and step S90 are referred to as the “first operation” and the “second operation” in this document, though in some examples there may be other operations that occur prior to S30, there may be operations that occur between S30 and S90, and/or other changes to order may occur. This final operation makes it possible to obtain refined estimates of the codevectors. Using reverse operations (such as based on a permute and a reverse permute logic) makes it possible to reduce the memory footprint.

The above method is typically performed iteratively, until a convergence is achieved. That is, the steps of feeding S20 the product vector, performing S30 the first operation, feeding S40 the quasi-orthogonal vectors, and performing S90 the second operation, are repeatedly performed based on successively refined estimates of the codevectors. The process can be repeated a predetermined number of times or until a suitable convergence criterion is met. A suitable convergence criterion is one where the following equalities are verified: \hat{α}(t+1)=\hat{α}(t), \hat{b}(t+1)=\hat{b}(t), and ĉ(t+1)=ĉ(t), as noted above.

The present disclosure proposes to feed quasi-orthogonalized versions of current estimates of the codevectors (i.e., the unbound codevectors), as obtained after the unbinding step, to the next modules of the resonator network, with a view to determining refined estimates of the codevectors. This is achieved using a single codebook, instead of using several codebooks, as in prior art methods. Using a single codebook simplifies data memory accesses, as well as the storage of the corresponding data. That is, a single memory space or buffer need be populated and accessed. In addition, a single storage device may be needed, which aggregates all the required data, as in embodiments discussed later. All the more, the proposed approach makes it possible to multiplex the quasi-orthogonal vectors, with a view to processing them across a single channel (as assumed in FIG. 1), which substantially accelerates processing times too. Finally, the proposed approach allows scalable, hardware-friendly realization of the resonator network modules, as in embodiments discussed below in detail.

The quasi-orthogonal vectors are nearly orthogonal representations of the code vectors. The modified versions of the vectors need not be fully orthogonal. It is sufficient for them to be quasi orthogonal. Aspects of the present disclosure relate to the use of quasi orthogonal vectors in high-dimensional computing, where the vector dimensions are typically between 1,000 and 10,000. Still, aspects of this disclosure include the use of lower vector dimensions (e.g., 100 to 1,000), although this typically requires adapting the thresholds used during the activation phase, as in embodiments described below.

The following paragraph describes the concept of quasi-orthogonal vector. Consider a set of vectors v∈{−1, 1}^{N}, where the coordinates of any vector of v are chosen independently to be ±1 (i.e., +1 half the time, −1 half the time, on average). Then the expected value of the square of the scalar product of any two vectors is small when N is sufficiently large. That is, |v₁·v₂|²/(|v₁|²|v₂|²) is equal to 1/N, on average. In other words, the expected value of cos² (θ), where θ is the angle formed between any two randomly chosen vectors in this set, is 1/N. I.e., randomly chosen vectors are reasonably orthogonal to one another if N is large. So, quasi-orthogonal means that the absolute value of the scalar product of any two vectors is substantially smaller than the product of the norms of the two vectors or, conversely, that the absolute value of the cosine of the angle between the two vectors is substantially smaller than 1 (typically less than 0.032 for N>1,000). Again, the vectors only need to be at least quasi-orthogonal. They may possibly be fully (i.e., strictly) orthogonal, although this is not necessary, given the dimensionality at issue. In the present context, the unbound codevectors are quasi-orthogonalize at each time step t, which amounts to replace the unbound codevectors (as typically obtained by a usual resonator network) by quasi-orthogonalized versions thereof in the normal resonator flow. Yet, the proposed approach further includes applying an inverse operation, at the end of each iteration, in order to form correct estimates of the codevectors.

The processing of the quasi-orthogonal vectors can be multiplexed, because a single codebook is used. That is, in embodiments, the step of feeding S40 the quasi-orthogonal vectors to the search-in-superposition modules 12, 14 comprises multiplexing the quasi-orthogonal vectors obtained, as assumed in FIG. 1, e.g., utilizing a multiplexing unit 156 (see FIG. 2). The multiplexed vectors are then fed to the search-in-superposition modules 12, 14 to obtain S50-S80 transformed multiplexed vectors by utilizing the single codebook. In addition, the method further comprises demultiplexing S90 the transformed multiplexed vectors to obtain the transformed vectors, prior to performing the second operation, in order to retrieve the correct codevector estimates.

That is, the n quasi-orthogonalized vectors are processed through a unique channel, one after the other, contrary to prior approaches. I.e., instead of having n channels involving n codebooks, here a single channel and a single codebook are used. In a software implementation, it is sufficient to store and load a single codebook, which saves time and energy. In some embodiments, which involve dedicated hardware (e.g., involving an in-memory processing device), a single processing device is needed, which stores all the required codevector values, as described later in detail.

As evoked earlier, the search-in-superposition modules 12, 14 can include, on the one hand, an associative search module 12 and, on the other hand, a weighted superposition module 14, which sequentially process the vectors. Thus, the step of feeding the quasi-orthogonal vectors to the search-in-superposition modules 12, 14 decomposes into two distinct steps, in accordance with the fact that the search-in-superposition modules 12, 14 decompose into two distinct modules. Feeding the quasi-orthogonal vectors to the search-in-superposition modules 12, 14 causes the sequentially feeding S40 of the quasi-orthogonal vectors to the associative search module 12 and then passes S70 vectors accordingly obtained to the weighted superposition module 14. The associative search module 12 computes S50 similarity vectors (or attention vectors) based on a transpose of the single codebook. In turn, the similarity vectors are passed S70 to the weighted superposition module 14, in order for the weighted superposition module 14 to compute S80 weighted superimposed vectors based on the single codebook. However, an intermediate (activation) module 13 may possibly be interconnected between modules 12 and 14, which further processes the similarity vectors. Thus, the present methods can pass vectors obtained from the similarity vectors to the weighted superposition module 14, instead of directly passing the similarity vectors, as discussed later in detail.

Note, the last module can further bipolarize S100 vector components of the weighted, superimposed vectors, e.g., by applying a sign function, as discussed in the background section. In variants, this last step may also be performed by a further module (not shown) connected in output of the module 14.

The single codebook may be chosen to be symmetric, such that it is equal to its transpose. In that case, a same representation of the single codebook is used by each of the associative search module 12 and the weighted superposition module 14. In addition, the single codebook may be stored in a same physical storage, and possibly be loaded (as a whole) in the same main memory, if necessary (i.e., in software implementations).

However, the present methods may rely on dedicated hardware, which includes one or more crossbar array structures, as now discussed in reference to FIG. 2. Each crossbar array includes input lines 161 and output lines 162, which are arranged in rows and columns. The input lines 161 and the output lines 162 are interconnected via memory elements 165. By suitably programming S45 its memory elements 165, a crossbar array structure 16 can be used to efficiently perform MVM operations. Thus, a crossbar array structure 16 can be configured to act as the associative search module 12 or the weighted superposition module 14, provided that suitable signals are injected through the input lines 161. The injected signals encode the vectors to be matrix-vector multiplied to the codebook vectors, while the memory elements 165 store the codebook vector values.

If necessary, two crossbar array structures may be cascaded and configured as the associative search module 12 and the weighted superposition module 14, respectively, of the resonator network. In the first case, the codevectors that together form the codebook are stored row-wise, i.e., across respective rows, while the codevectors are stored column-wise in the second case stores a codevector, so as to store transposed versions of the same codebook. In the example of FIG. 2, however, a single crossbar array structure 16 is used, because the single codebook in use is assumed to be symmetric. Thus, the same crossbar array can store the same codebook vector elements and be used to successively play the role of the associative search module 12 and the weighted superposition module 14.

In detail, each of the modules 12 and 14 perform MVM operations. The module 12 operates based on vector components of the quasi-orthogonal vectors, injected from the input lines, whereas the module 14 operates based on vector components of the similarity vectors or components of activated vectors obtained in output of an intermediate module 13, see below. Now, owing to the single, symmetric codebook, a same crossbar array 16 can store the codebook vector elements and successively perform the MVM operations required by the associative search module 12 and the weighted superposition module 14.

As evoked above, the modules 12-14 may include an activation module 13, which interconnects the associative search module 12 with the weighted superposition module 14, as assumed in FIG. 1. In that case, feeding S40 the quasi-orthogonal vectors to the search-in-superposition modules 12, 14 causes the similarity vectors (as obtained in output of module 12) to be passed to the activation module 13. The activation module 13 selectively activates S60 vector components of the similarity vectors and accordingly produces activated vectors. Next, the activated vectors are passed S70 to the weighted superposition module 14.

The similarity vectors α_{α}(t), α_{b}(t), and α_{c}(t) obtained in output of module 12 may be processed through a non-linear activation function ƒ(·), which produces the activated vectors. The activated vectors are then passed to the weighted superposition module 14, to obtain the weighted superimposed vectors.

More generally, various types of activation functions can be contemplated. In some embodiments non-linear functions are used, such as functions relying on a sorting algorithm or allowing, e.g., 50% of the values to be activated, using a mean-based approach or a threshold-based approach. If necessary, the present methods may further comprise sparsifying the attention vectors of the codebooks. This may notably cause the sole top-K values in the attention vectors to be activated, where K<<M. I.e., K is much smaller than M, which is the number of non-zero elements/total number of vector elements TBC. In variants, the sparsification is achieved by activating only the elements of the attention vectors that are larger than the mean of the elements or a threshold, as noted above. Such activation techniques can be used to reduce the computational effort and also increase the size of solvable problems, typically by one order of magnitude for a fixed vector dimension.

In some embodiments, the first and second operations (i.e., the operations performed at steps S30 and S90) involve permutations. More precisely, the first operation is a vector-dependent permutation operation, which permutes S30 vector components of the unbound vectors according to respective permutation schemes. That is, vector components of each of the unbound vectors are permuted according to a respective permutation scheme, such that each vector is subject to a distinct permutation scheme. The second operation permutes S90 vector components of the transformed vectors according to inverse operations, i.e., inverses of the permutation schemes used in the first operation.

Each permutation scheme can involve cyclic shifting operations over the vector components. Such operations are quickly performed, at a low computational cost. For example, the cyclic shifting operations may be designed so as to cause the vector components of the k^{th} vector of the unbound vectors to cyclically shift S30, S90 by k−1. E.g., vector components of the k^{th} vector can first be cyclically shifted to the right, by 1 (step S30). The inverse operation (step S90) then simply consists of cyclically shifting components to the left, by 1.

Other types of permutations can similarly be contemplated, e.g., which cyclically shift the vector components of the k^{th} vector by k−2, or k−3, etc., either to the left or to the right. Again, the inverse operations are straightforward. Moreover, random permutations can be used too. More generally, various “shuffling” algorithms can be contemplated (which shuffle vector components). Such operations cause the vectors to randomize, making them quasi-orthogonal, owing to their dimensions, in contrast with the codebook estimates outputted from module 11.

FIG. 3 shows an exemplary flow of operation. A given input vector (a product vector) is received at step S10. Trial codevectors are initialized (e.g., randomly) at step S15. At step S20, the input vector and the initial codevectors are fed to the unbinding module 11, to produce unbound vectors. At step S30, vector components of the unbound vectors undergo a permutation to produce quasi-orthogonal vectors. At step S40, the quasi-orthogonal vectors are multiplexed, and the resulting signals are applied to the crossbar array. The crossbar array is assumed to have been suitably programmed S45 to store vector components of a symmetric codebook in this example. The crossbar array, which first acts as the associative search module, computes similarity vectors by utilizing MVM operations based on the symmetric codebook. At step S60, vector components of the similarity vectors are activated. At step S70, the activated vectors are re-injected to the crossbar array, which now acts as a weighted superposition module, to compute S80 weighted superimposed vectors, again based on the symmetric codebook. The resulting vectors are demultiplexed and then unpermuted at step S90. Such vectors are subsequently bipolarized S100. The vectors finally obtained S110 are refined estimates of the codevectors. The above process is repeated (S120: No, the process loops back to step S20), based on iteratively refined estimates of the codevectors, until a termination criterion is met. If so (S120: Yes), the last version of the codevectors is returned and the process stops S130.

Referring to FIGS. 1, 2, and 4, another aspect of the disclosure is now described in detail, which concerns a computerized system 1 for factorizing a vector. The system 1 includes a resonator network unit, an input unit 17, and processor(s) 15, 105.

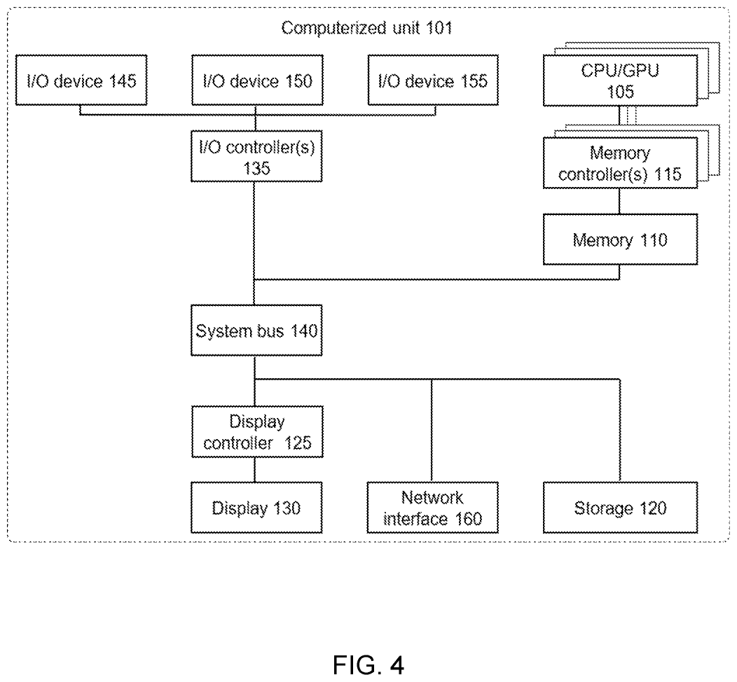

The resonator network unit is designed to enable an unbinding module 11 and search-in-superposition modules 12, 14, as schematically depicted in the diagram of FIG. 1. The resonator network unit can be implemented in software, utilizing conventional hardware (including conventional processor 105 and memory 110). That is, at least some of the modules 11-14 of the resonator network unit can possibly be implemented in software, using conventional computerized means such as the computerized unit 101 shown in FIG. 4. In some embodiments, however, the modules 11-14 are implemented by way of non-conventional hardware devices, such as the dedicated hardware unit 16 shown in FIG. 2, which comprises one or more crossbar array structures and is operated utilizing dedicated processor 15.

The input unit 17 is notably configured to feed an input vector (i.e., the product vector to be factorized) to the unbinding module 11. This, in operation, causes unbound vectors to be obtained, where these unbound vectors represent estimates of codevectors of the product vector, owing to the configuration of the unbinding module 11.

Consistently with the present methods, the processor(s) 15, 105 are configured to perform the first operation, feed the quasi-orthogonal vectors to the search-in-superposition modules 12, 14, and perform the second operation. As described earlier, the first operation is reversible; it is performed on the unbound vectors, so as to obtain quasi-orthogonal vectors. In addition, feeding the quasi-orthogonal vectors to the modules 12, 14 causes transformed vectors to be obtain by utilizing a single codebook, in operation. Finally, the second operation, which is the inverse operation of the first operation, is performed on the transformed vectors, to obtain refined estimates of the codevectors. Again, the above process can be iterated until convergence is achieved. I.e., the system 1 forms a closed circuit that iteratively refines estimates of the codevectors, until a convergence is met.

Consistently with the present methods, the search-in-superposition modules 12, 14 enabled by the resonator network unit may include an associative search module 12 and a weighted superposition module 14. As explained earlier, the associative search module 12 is configured to compute similarity vectors based on the quasi-orthogonal vectors and a transpose of the single codebook. The weighted superposition module 14 is configured to compute weighted superimposed vectors based on vectors obtained from the similarity vectors and the single codebook. Again, the last module 14 can further bipolarize vector components of the weighted, superimposed vectors, e.g., by applying the sign function, although this can also be performed by a further module (not shown) in output of the weighted superposition module 14.

Moreover, the search-in-superposition modules 12-14 may include an activation module 13, which interconnects the associative search module 12 with the weighted superposition module 14. The activation module 13 is configured to selectively activate vector components of the similarity vectors to accordingly obtain activated vectors. This module 13 further passes the activated vectors to the weighted superposition module 14, in operation.

The following describes embodiments of the system 1 that rely on non-conventional hardware. As seen in FIG. 2, the processor 15 of the computerized system 1 may include a multiplexing unit 156. The latter is configured to multiplex the quasi-orthogonal vectors obtained by the processing unit into multiplexed signals. In turn, the multiplexed signals are applied to the search-in-superposition modules 12, 14, one by one and one after the other. This makes it possible to obtain output signals encoding transformed multiplexed vectors (utilizing the single codebook). In addition, the processor 15 includes a demultiplexing unit 154, which is configured to read the output signals and demultiplex the transformed multiplexed vectors encoded therein to obtain the transformed vectors.

In some embodiments, the resonator network unit includes one or more crossbar array structures 16. The structure 16 includes input lines 161 and output lines 162, which are arranged in rows and columns and are interconnected via memory elements 165. That is, the input lines and output lines are interconnected at cross-points. The cross-points define respective cells. I.e., each cross-point is associated with a respective cell. The cells include respective memory elements αᵢⱼ. Overall, the crossbar array structure 16 includes a set of memory elements αᵢⱼ. In some embodiments, the memory elements 165 of the device 1 are resistive memory elements. In such embodiments, such resistive memory elements can be selected among phase-change memory (PCM), resistive random access memory (RRAM or ReRAM), and magnetoresistive random access memory (MRAM) elements. Still, other types of memory elements can be contemplated, such as flash cells, as known in the art.

Beside their low-power consumption, resistive memory elements may be leveraged to implement operations required by the resonator network modules 12, 14. To that aim, the system 1 further includes programming means 10, which are connected in input of the input lines 161 and are adapted to program the memory elements 165 of the crossbar array structure 16. This makes it possible to configure a crossbar array structure 16 as the associative search module 12 or the weighted superposition module 14. The system 1 may include a single crossbar 16, given that it may rely on a symmetric codebook. I.e., the crossbar 16 can be programmed S45 to play the role of each of the associative search module 12 and the weighted superposition module 14. In variants (not shown), the system may include two crossbars, which are cascaded, programmed, and thus configured, as the associative search module 12 and the weighted superposition module 14, respectively.

Note, the programming unit 10 may not only serve to write values to the resistive elements 165 but, in addition, to apply input signals to the input lines 161, so as to enable MVM operations of the modules 12, 14.

The activation module 13 can for instance be embodied as a near-memory processing element 13 connected to the crossbar array 16. In the example of FIG. 2, this processing element in connected in output of the output lines 162 (in the east region) of the crossbar array 16. This way, not only the module 13 can read out signals obtained in output of the input lines 161 but, in addition, it can feed signals back to the input lines 161, from the east region. I.e., the symmetry of the crossbar 16 is mapped to the symmetry of the MVM operations performed by the modules 12 and 14.

In the example of FIG. 2, the processor 15 serves to both (de)multiplex vectors and permute vector components. It is connected to output lines 162 of the columns (south region) of the array 16. More precisely, the processor 15 includes a permutation unit 153, which allows the first operation to be performed as a vector-dependent permutation operation. I.e., the processor 15 causes the vector components of the unbound vectors to undergo permutations (e.g., it permutes the vector components, as occasionally discussed herein) according to respective permutation schemes (vector components of each unbound vector are permuted according to a respective permutation scheme), in operation. Similarly, the permutation unit 153 can perform the second operation as a vector-dependent, inverse permutation operation, which permutes vector components of the transformed vectors according to inverse permutation schemes, in operation.

As explained earlier, the permutation unit 153 may be designed to implement each permutation as cyclic shifting operations. In particular, the cyclic shifting operations may cause the vector components of any k^{th} vector of the unbound vectors by k−1 to cyclically shift, in operation.

In the example of FIG. 2, the permutation unit 153 is a digital processing unit, which connects to the output lines 162 via digital-to-analog convertors (DACs) 151 and analog-to-digital convertors (ADCs) 152. The DACs 151 and ADCs 152 are alternatively selected to inject signals to the crossbar array structure 16 and read out signals from the crossbar array structure 16. The unbinding operation is performed via a conventional or dedicated hardware unit 11 (e.g., digitally, since the neighboring operations are performed in the digital space too), based on the input vector. The product vector is input via a dedicated input unit 17, which typically forms part of an input/output unit, typically a computer (or module) that is able to communicate with an external computerized unit (not shown).

The very first unbinding operation is performed utilizing suitably initialized codevectors. At the subsequent iterations, refined estimates of the codevectors are used for the unbinding operations. Such codevectors are fed one after the other, via the multiplexer 156. Next, a permutation is performed on the unbound vectors via the unit 153 to obtain quasi-orthogonal vectors. The latter are subsequently injected in the crossbar array structure 16 via the DACs 151. The elements 156 store the codebook vector components (the codebook is symmetric). The MVM operations performed by the crossbar array structure 16, acting as module 12, produce signals encoding similarity vectors based on the single codebook.

Such signals are read by the eastern unit 13, embodying the activation module 13. I.e., the similarity vectors are passed to the activation module 13, for it to selectively activate vector components of the similarity vectors and accordingly obtain activated vectors. The activated vectors are then passed (from the east region) to the crossbar array structure 16 (now acting as the weighted superposition module 14) to produce signals encoding the weighted superimposed vectors. Such signals are then read out by the unit 153, via the ADCs 152, to perform the second operation (unpermute), prior to bipolarizing the vector components. This way, refined estimates of the codevectors are obtained, which can be used to start a new iteration.

The above description of the operations assumes that use is made of the dedicated hardware device shown in FIG. 2. In variants, such operations can be performed in software, using conventional hardware such as the computerized unit 101 shown in FIG. 4. In further variants, the present operations are performed utilizing a mix of conventional hardware (performing operations in the digital space) and non-conventional hardware (e.g., including a crossbar array 16 as described above).

In that respect, a final aspect of the disclosure concerns a computer program product for factorizing a vector by utilizing modules 12-14 of a resonator network, enabled in software. The computer program product comprises a computer-readable storage medium having computer-readable program code embodied therewith. The computer-readable program code can be evoked by processor 105 (e.g., of the computerized unit 101) to cause the processor 105 to perform steps as described above, i.e., feed (or instruct to feed) a product vector to the unbinding module 11 to obtain unbound vectors, perform a first (reversible) operation on the unbound vectors to obtain quasi-orthogonal vectors, feed (or instruct to feed) the quasi-orthogonal vectors to the search-in-superposition modules 12, 14 to obtain transformed vectors by utilizing a single codebook, and perform a second (inverse) operation on the transformed vectors, to obtained refined estimates of the codevectors. Again, this is typically done iteratively. The computerized unit 101 is discussed in detail in section 2.1. Additional aspects of the present computer program products are discussed in section 2.2.

Computerized devices can be suitably designed for implementing embodiments of the present disclosure as described herein. In that respect, it can be appreciated that the methods described herein are largely non-interactive and automated. In exemplary embodiments, the methods described herein can be implemented either in an interactive, partly-interactive or non-interactive system. The methods described herein can be implemented in software (e.g., firmware), hardware, or a combination thereof. In exemplary embodiments, the methods described herein are implemented in software, as an executable program, the latter executed by suitable digital processing devices. More generally, embodiments of the present disclosure can be implemented wherein general-purpose digital computers, such as personal computers, workstations, etc., are used.

For instance, FIG. 4 schematically represents a computerized unit 101, e.g., a general-purpose computer. In exemplary embodiments, in terms of hardware architecture, as shown in FIG. 4, the unit 101 includes a processor 105, memory 110 coupled to a memory controller 115, and one or more input and/or output (I/O) devices 145, 150, 155 (or peripherals) that are communicatively coupled via a local input/output controller 135. The input/output controller 135 can be, but is not limited to, one or more buses 140 or other wired or wireless connections, as is known in the art. The input/output controller 135 may have additional elements, which are omitted for simplicity, such as controllers, buffers (caches), drivers, repeaters, and receivers, to enable communications. Further, the local interface may include address, control, and/or data connections to enable appropriate communications among the aforementioned components.

The processor 105 is a hardware device for executing software, particularly that stored in memory 110. The processor 105 can be any custom made or commercially available processor, a central processing unit (CPU), a set of CPUs, an auxiliary processor among several processors associated with the computer 101, a semiconductor based microprocessor (in the form of a microchip or chip set), or generally any device for executing software instructions. It may further include a graphics processing unit (GPU) or a set of GPUs.

The memory 110 can include any one or combination of volatile memory elements (e.g., random access memory) and nonvolatile memory elements. Moreover, the memory 110 may incorporate electronic, magnetic, optical, and/or other types of storage media. Note that the memory 110 can have a distributed architecture, where various components are situated remote from one another, but can be accessed by the processor 105.

The software in memory 110 may include one or more separate programs, each of which comprises an ordered listing of executable instructions for implementing logical functions. In the example of FIG. 4, the software in the memory 110 includes methods described herein in accordance with exemplary embodiments and a suitable operating system (OS). The OS essentially controls the execution of other computer programs and provides scheduling, input-output control, file and data management, memory management, and communication control and related services.

The methods described herein may be in the form of a source program, executable program (object code), script, or any other entity comprising a set of instructions to be performed. When in a source program form, then the program needs to be translated via a compiler, assembler, interpreter, or the like, as known per se, which may or may not be included within the memory 110, so as to operate properly in connection with the OS. Furthermore, the methods can be written as an object oriented programming language, which has classes of data and methods, or a procedure programming language, which has routines, subroutines, and/or functions.

Possibly, a conventional keyboard 150 and mouse 155 can be coupled to the input/output controller 135. Other I/O devices 145-155 may include other hardware devices. In addition, the I/O devices 145-155 may further include devices that communicate both inputs and outputs. The system 100 can further include a display controller 125 coupled to a display 130. In exemplary embodiments, the system 100 can further include a network interface or transceiver 160 for coupling to a network.

The network transmits and receives data between the unit 101 and external systems. The network is possibly implemented in a wireless fashion, e.g., using wireless protocols and technologies, such as WiFi, WiMax, etc. The network may be a fixed wireless network, a wireless local area network (LAN), a wireless wide area network (WAN) a personal area network (PAN), a virtual private network (VPN), intranet or other suitable network system and includes equipment for receiving and transmitting signals.

The network can also be an IP-based network for communication between the unit 101 and any external server, client and the like via a broadband connection. In exemplary embodiments, network can be a managed IP network administered by a service provider. Besides, the network can be a packet-switched network such as a LAN, WAN, Internet network, etc.

If the unit 101 is a PC, workstation, intelligent device or the like, the software in the memory 110 may further include a basic input output system (BIOS). The BIOS is stored in ROM so that the BIOS can be executed when the computer 101 is activated.

When the unit 101 is in operation, the processor 105 is configured to execute software stored within the memory 110, to communicate data to and from the memory 110, and to generally control operations of the computer 101 pursuant to the software. The methods described herein and the OS, in whole or in part are read by the processor 105, typically buffered within the processor 105, and then executed. When the methods described herein are implemented in software, the methods can be stored on any computer readable medium, such as storage 120, for use by or in connection with any computer related system or method.

The present disclosure may be a system, a method, and/or a computer program product at any possible technical detail level of integration. The computer program product may include a computer readable storage medium (or media) having computer readable program instructions thereon for causing a processor to carry out aspects of the present disclosure. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the C programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the present disclosure has been described with reference to a limited number of embodiments, variants and the accompanying drawings, it will be understood by those skilled in the art that various changes may be made, and equivalents may be substituted without departing from the scope of the present disclosure. In particular, a feature (device-like or method-like) recited in a given embodiment, variant or shown in a drawing may be combined with or replace another feature in another embodiment, variant or drawing, without departing from the scope of the present disclosure. Various combinations of the features described in respect of any of the above embodiments or variants may accordingly be contemplated, that remain within the scope of the appended claims. In addition, many minor modifications may be made to adapt a particular situation or material to the teachings of the present disclosure without departing from its scope. Therefore, it is intended that the present disclosure not be limited to the particular embodiments disclosed, but that the present disclosure will include all embodiments falling within the scope of the appended claims. In addition, many other variants than explicitly touched above can be contemplated.

What is claimed is:

1. A computer-implemented method, the method comprising:
feeding a product vector to an unbinding module to obtain unbound vectors representing estimates of codevectors of a product vector;
performing a first operation on the unbound vectors to obtain quasi-orthogonal vectors, wherein the first operation is reversible;
feeding the quasi-orthogonal vectors to search-in-superposition modules to obtain transformed vectors by utilizing a single codebook; and
performing a second operation on the transformed vectors, wherein the second operation is an inverse operation of the first operation, to obtain refined estimates of the codevectors.

2. The method according to claim 1, wherein:
feeding the quasi-orthogonal vectors to the search-in-superposition modules comprises:
multiplexing the quasi-orthogonal vectors obtained; and
feeding the multiplexed vectors to the search-in-superposition modules to
obtain transformed multiplexed vectors by utilizing the single codebook, and
the method further comprises, prior to performing the second operation, demultiplexing the transformed multiplexed vectors to obtain the transformed vectors.

3. The method according to claim 1, wherein the search-in-superposition modules includes an associative search module and a weighted superposition module, whereby feeding the quasi-orthogonal vectors to the search-in-superposition modules causes the search-in-superposition modules to sequentially:
feed the quasi-orthogonal vectors to the associative search module, for it to compute similarity vectors based on a transpose of the single codebook, and
pass vectors obtained from the similarity vectors to the weighted superposition module, for the weighted superposition module to compute weighted superimposed vectors based on the single codebook.

4. The method according to claim 3, wherein the single codebook is symmetric, such that the single codebook is equal to a transpose of the single codebook, whereby a same representation of the single codebook is used by each of the associative search module and the weighted superposition module.

5. The method according to claim 4, wherein:
each of the associative search module and the weighted superposition module is embodied as a crossbar array structure including input lines and output lines arranged in rows and columns, the input lines and output lines interconnected via memory elements, and
the method further comprises programming the memory elements of the crossbar array structure to configure the latter as one or each of the associative search module and the weighted superposition module.

6. The method according to claim 3, wherein the search-in-superposition modules further include an activation module interconnecting the associative search module with the weighted superposition module, whereby feeding the quasi-orthogonal vectors to the search-in-superposition modules further causes the similarity vectors to be passed to the activation module to selectively activate vector components of the similarity vectors and accordingly obtain activated vectors, and pass the activated vectors to the weighted superposition module.

7. The method according to claim 1, wherein the first operation is a vector-dependent permutation operation, which permutes vector components of the unbound vectors according to respective permutation schemes, whereby vector components of each of the unbound vectors are permuted according to a respective one of the permutation schemes, whereas the second operation permutes vector components of the transformed vectors according to inverses of the respective permutation schemes.

8. The method according to claim 7, wherein each of the respective permutation schemes involves cyclic shifting operations.

9. The method according to claim 7, wherein the cyclic shifting operations cyclically shifts the vector components of any k^{th} vector of the unbound vectors by k−1.

10. The method according to claim 1, wherein the method is iteratively performed, whereby steps of feeding the product vector, performing the first operation, feeding the quasi-orthogonal vectors, and performing the second operation, are repeatedly performed based on successively refined estimates of the codevectors.

11. A computerized system, the system including
a resonator network unit, which is configured to enable an unbinding module and search-in-superposition modules;
an input unit configured to feed a product vector to the unbinding module to obtain unbound vectors representing estimates of codevectors of the product vector; and
a processor and memory to store instructions, wherein the instructions are executed by the processor to:
perform a first operation on the unbound vectors to obtain quasi-orthogonal vectors, wherein the first operation is reversible;
feed the quasi-orthogonal vectors to the search-in-superposition modules to obtain transformed vectors by utilizing a single codebook; and
perform a second operation on the transformed vectors, wherein the second operation is an inverse operation of the first operation, to obtained refined estimates of the codevectors.

12. The computerized system according to claim 11, wherein the processor further comprises:
a multiplexing unit configured to multiplex the quasi-orthogonal vectors obtained by the processing unit into multiplexed signals and apply the multiplexed signals to the search-in-superposition modules to obtain, by utilizing the single codebook, output signals encoding transformed multiplexed vectors, and
a demultiplexing unit configured to read the output signals and demultiplex the transformed multiplexed vectors encoded therein to obtain the transformed vectors.

13. The computerized system according to claim 11, wherein the search-in-superposition modules includes:
an associative search module, which is configured to compute similarity vectors based on the quasi-orthogonal vectors and a transpose of the single codebook; and
a weighted superposition module, which is configured to compute weighted superimposed vectors based on vectors obtained from the similarity vectors and the single codebook.

14. The computerized system according to claim 13, wherein:
the search-in-superposition modules further includes an activation module interconnecting the associative search module with the weighted superposition module, and
the activation module is configured to:
selectively activate vector components of the similarity vectors to accordingly obtain activated vectors, and
pass the activated vectors to the weighted superposition module.

15. The computerized system according to claim 13, wherein:
the resonator network unit includes a crossbar array structure including input lines and output lines arranged in rows and columns, which are interconnected via memory elements, and
the system further includes programming means connected in input of the input lines and adapted to program the memory elements of the crossbar array structure to accordingly configure the crossbar array structure as said associative search module or said weighted superposition module.

16. The computerized system according to claim 11, wherein:
the processor includes a permutation unit configured to perform:
the first operation as a vector-dependent permutation operation, which permutes vector components of the unbound vectors according to respective permutation schemes, whereby vector components of each of the unbound vectors are permuted according to a respective one of the respective permutation schemes, in operation, and
the second operation as a vector-dependent, inverse permutation operation, which permutes vector components of the transformed vectors according to permutation schemes that are inverses of the respective permutation schemes, in operation.

17. The computerized system according to claim 16, wherein the permutation unit is adapted to implement each of the respective permutation schemes as cyclic shifting operations.

18. The computerized system according to claim 17, wherein the cyclic shifting operations cyclically shifts the vector components of any k^{th} vector of the unbound vectors by k−1, in operation.

19. The computerized system according to claim 11, wherein the system is configured to iteratively refine the estimates of the codevectors.

20. A computer program, the computer program product comprising a computer-readable storage medium having computer-readable program code embodied therewith, wherein the computer-readable program code can be evoked by processor to cause the processor to:
feed a product vector to an unbinding module to obtain unbound vectors representing estimates of codevectors of the product vector;
perform a first operation on the unbound vectors to obtain quasi-orthogonal vectors, wherein the first operation is reversible;
feed the quasi-orthogonal vectors to search-in-superposition modules to obtain transformed vectors by utilizing a single codebook; and
perform a second operation on the transformed vectors, wherein the second operation is an inverse operation of the first operation, to obtained refined estimates of the codevectors.
